(19) United States
(12) Patent Application Publication
(10) Pub. No.: US 2017/0073222 A1
(43) Pub. Date: Mar. 16, 2017

(54) ELECTRONIC SYSTEM, AS WELL AS MANUFACTURING METHOD, AND DEVICE FOR MANUFACTURING AN ELECTRONIC SYSTEM

(71) Applicant: Robert Bosch GmbH, Stuttgart (DE)

(72) Inventors: Rolf KAACK, Reutlingen (DE); Mathias BRUENDEL, Stuttgart (DE); Lisa Marie HAAS, Bempflingen (DE)

(21) Appl. No.: 15/120,324

(22) PCT Filed: Feb. 6, 2015
(86) PCT No.: PCT/EP2015/052510

§ 371 Date: Aug. 19, 2016

(30) Foreign Application Priority Data
Feb. 25, 2014 (DE) 102014203385.3

(51) Int. Cl. B81B 7/00; G06F 17/50; B81C 1/00

(52) U.S. Cl. CPC B81B 7/0074; B81C 1/00333; G06F 17/5072; G06F 2217/40

(57) ABSTRACT

An electronic system having a carrier, at least one radio chip mounted on the carrier, a spacer element, which is mounted on the radio chip and features a material having a predefined permittivity number, and at least one electronic component mounted on the radio chip.

### FIELD OF THE INVENTION

The present invention relates to an electronic system, to a method for manufacturing an electronic system, to a device for manufacturing an electronic system, as well as to a corresponding computer program product.

### BACKGROUND INFORMATION

It is believed that many IC chips, that is, semiconductor substrates having electronic circuits disposed thereon, are individually bonded and molded in a housing. There have always been molded housings that contain two or more chips. This holds for acceleration sensors, rotation-rate sensors and combination sensors, for example. Increasing miniaturization and higher levels of integration require that ever more chips, for example, two MEMS chips, three ASICs, and one microcontroller be installed in one housing. In keeping with developments in the “Internet of Things” sector, the next integration step is to combine MEMS sensors with microcontrollers and a radio chip in a highly integrated molded housing (for example, BGA, LGA).

### SUMMARY OF THE INVENTION

Against this background, the approach presented here introduces an electronic system composed, for example, of at least one radio chip, as well as of at least one further IC (ASIC, sensor, microcontroller). Advantageous embodiments will become apparent from the respective dependent claims and the following description.

To install the above-mentioned electronic components, they are advantageously stacked in a molded housing to minimize the space consumed on the printed circuit board and thereby achieve a decisive advantage over an installation of individual components. Here, the components having larger lateral dimensions are expediently located further down in the stack. This can lead to the radio chip being the lowermost component or one of the bottom components in the stack.

A significant challenge arises when radio chips are installed in a stack. The components, which are placed over the radio chip, can degrade the proper functioning thereof. Such degradations can even prevent the radio chip from functioning in a specified range, thus, for example, induce a change in the output or even result in a shifting of the transmit and receive frequencies. The result can be that the radio chip is no longer able to communicate with other devices.

An example would be a radio chip, which is configured to transmit in accordance with Bluetooth Specification 4.0, but whose frequency generator is influenced by the other components due to the stacked configuration thereof. This can prevent the radio chip from sending the “advertising” packets thereof on the specified channels 38, 39 and 40, but, in an undefined manner, alongside, making it no longer visible to other Bluetooth devices.

The properties of the radio chip are influenced by the surroundings thereof. The radio chip is normally located in a molded housing and is covered by the mold. The transmission properties of the radio chip are affected by this material due to the dielectric conductivity, thus the permittivity number thereof. The radio chip design must allow for this material, both in terms of the thickness thereof above the active transmission regions of the radio chip, and the permittivity number thereof.

When such a radio chip is installed with other chips and is located further down in the stack, it is inevitable that the material located above the radio chip must change. The material of the other components is typically silicon dioxide and has a substantially higher permittivity number than the mold material.

There are basically two strategies to nevertheless ensure that the radio chip will reliably transmit in the specified range over the entire specified application range (temperature, supply voltage, available external oscillators). First of all, the radio chip could be reconfigured and adapted to the new surroundings. However, this would entail significant costs.

The present invention provides that a spacer element of sufficient thickness and having a permittivity number similar to that of the mold material be introduced above the radio chip. The radio chip may continue to transmit without limitation and independently of temperature.

In accordance with the concept presented here, housings, respectively SiPs (systems-in-package) may advantageously be realized where various chips, respectively electronic components are stacked on one radio chip. It is thus possible to successfully circumvent the need for a potential redesign of the radio chip.

An electronic system having the following features is presented:

a carrier;

at least one radio chip mounted on the carrier;

a spacer element, which is mounted on the radio chip and features a material having a predefined permittivity number; and

at least one electronic component mounted on or above the radio chip or the spacer element.

The electronic system may be understood to be an assemblage of the mentioned features that may each be in miniature. An electronic system of this kind may be used in the highly diverse “Internet of Things” sector, respectively “IoT” for wireless information processing and/or appliance control. The carrier maybe a substrate, respectively a printed circuit board for supporting the remaining components of the electrical system and/or for supplying the same with electric voltage. The radio chip may be understood to be an electronic component that is configured for transmitting and/or receiving electromagnetic radiation in a predefined or desired radio frequency band. The spacer element may be configured to ensure a predefined distance, in particular of the high-frequency portion of the radio chip, to components of the electrical system disposed above the radio chip, and thereby ensure a functioning in the specified range. ‘Spacer’ is the English term that is also commonly used to denote the spacer element. A permittivity number indicates a dielectric conductivity, respectively permeability of a medium for electric fields. ‘Dielectric constant’ is an often used, outdated synonym. The predefined permittivity number may be expressed as the relative permittivity, respectively permeability of the material in a ratio of the permittivity thereof to that of the vacuum, which is defined as a target quantity, on whose basis, the material in question was selected during the manufacture of the electronic system. The electronic component maybe a component from microsystems technology and/or electronics (ASICs), that is configured, in conjunction with the radio chip, to fulfill a predefined function of the electronic system. In particular, the carrier, the radio chip and the spacer element may be formed as layers, respectively plates and be directly stacked one over the other in the above mentioned sequence, the carrier forming the base of the stack.

In accordance with one specific embodiment of the electronic system presented here, the material of the spacer element may have a permittivity number, in particular of less than 10 and typically 3 to 5, that is within a tolerance range of the permittivity number of a molding compound surrounding the electronic component. The spacer element may thereby be completely or partially formed from the silicon dioxide. In this variant, the spacer element may be manufactured very cost-effectively.

The spacer element may also feature at least one further material having another predefined permittivity number. The further material maybe disposed on a first main side of the material facing the carrier and/or on a second main side of the material opposite the first main side and facing away from the carrier. This specific embodiment makes possible further functionalities that go beyond the spacing of the radio chip, in addition to allowing an even more accurate determination of the predefined permittivity number of the spacer elements.

For example, a predefined thickness of the spacer element may be between 50 and 200 μm. Particularly advantageous in this context is a specific embodiment of the approach introduced here where the predefined thickness of the spacer element is between 70 and 90 μm. The thickness may thereby denote a distance between a first main side and a second main side of the spacer element. The spacer element thickness provided here makes it possible to manufacture the electronic system in the miniature size that is especially advantageous for the Internet of Things.

In one specific embodiment of the electronic system, the material and/or the further material may be formed as an adhesive agent for adhering to a main side of the radio chip adjacent to the spacer element. This allows an element that is required anyway to assemble the electronic system to readily fulfill the additional function of spacing the radio chip at a distance. No costs, respectively only very little additional costs are incurred in the manufacture, and no engineering expenditure is entailed.

In accordance with another specific embodiment, the electronic system may also feature a housing. The housing may be configured to at least enclose the electronic component. Thus, the electronic system may be readily protected from external influences. Moreover, the individual components of the stacked electronic system may be additionally fixed in position.

In particular, within a tolerance range, the predefined permittivity number or a sum of the other predefined permittivity number and the other predefined permittivity number may correspond to a permittivity number of the housing. For example, the tolerance range may be conceived to not allow the predefined permittivity number or a sum of the other predefined permittivity number to deviate by more than 10 percent from the permittivity number of the housing. It is thus possible to advantageously eliminate the need for adapting, respectively modifying the frequency of the radio chip, thereby saving costs and time in the manufacture of the electronic system.

Also conceivable is a specific embodiment of the approach introduced here where the electronic component and/or the radio chip are/is configured as a processing unit for controlling at least an actuator and/or for analyzing information and/or as a sensor for recording at least one physical quantity. Such a specific embodiment of the present invention provides the advantage of a very compact design of an electronic system. Its application is characterized by substantial flexibility in different scenarios in terms of the surroundings thereof.

The electronic system may also include a further electronic component. The further electronic component may be configured on the electronic component, for example. This specific embodiment makes it advantageously possible to expand the electronic system by adding further functionalities. Thus, the electronic system may be used more versatilely and/or for more complex tasks.

For example, the electronic component may be configured as a processing unit for controlling and/or analyzing information of the other electronic component. The other electronic component may be configured as a sensor for recording a physical quantity, the electronic component, in particular, being configured as part of the radio chip. The electronic system presented here in this specific embodiment provides numerous possible applications in industry and in private use, here, in particular, in the increasingly important Internet of Things sector.

A method for manufacturing an electronic system is also presented, the manufacturing method including the following steps:

providing a carrier, a radio chip, an electronic component, and a spacer element that features a material having a predefined permittivity number;

mounting the radio chip on the carrier, the spacer element on the radio chip, and the electronic component on the spacer element in order to manufacture the electronic system.

The manufacturing method may be applied to an automated production line to allow an efficient manufacture of a multitude of the above described electronic systems.

A device for manufacturing an electronic system is also presented, the device having the following features:

a feeder device for providing a carrier, a radio chip, an electronic component, and a spacer element that features a material having a predefined permittivity number;

a positioning device for mounting the radio chip on the carrier, the spacer element on the radio chip, and the electronic component on the spacer element in order to manufacture the electronic system.

The device maybe used and configured in the above mentioned automated manufacturing process for implementing, respectively realizing the steps of a variant of the manufacturing method presented here in the devices thereof. This design variant of the present invention in the form of a device also makes it possible for the object of the present invention to be achieved rapidly and efficiently.

A device may be understood here to be an electrical device that processes sensor signals and outputs control and/or data signals as a function thereof. The device may have an interface implemented in hardware and/or software. When implemented in hardware, the interfaces may be part of what is commonly known as an ASIC system, for example, that includes a wide variety of device functions. However, the interfaces may also be separate, integrated circuits or be at least partly made up of discrete components. When implemented in software, the interfaces may be software modules that are present on a microcontroller, for example, in addition to other software modules.

A computer program product or a computer program having program code is also advantageous that may be stored on a machine-readable medium or storage medium, such as a semiconductor memory, a hard-disk memory or an optical memory, and is used for implementing, realizing and/or controlling the steps of the method in accordance with one of the above described specific embodiments, in particular, when the program product or program is executed on a computer or a device.

The approach presented here is described in greater detail in the following with reference to the enclosed drawings.

### BRIEF DESCRIPTION OF THE DRAWINGS

FIG. 1 a schematic representation of an electronic system having a radio chip in accordance with the related art.

FIG. 2 a schematic representation of an electronic system having a radio chip and spacer element in accordance with an exemplary embodiment of the present invention.

FIG. 3 a schematic representation of an electronic system having a radio chip and a two-part spacer element in accordance with an exemplary embodiment of the present invention.

FIG. 4 a schematic representation of an electronic system having a radio chip and adhesive agent as a spacer element in accordance with an exemplary embodiment of the present invention.

FIG. 5 a flow chart of a method for manufacturing an electronic system, in accordance with an exemplary embodiment of the present invention.

FIG. 6 a block diagram of a device for manufacturing an electronic system, in accordance with an exemplary embodiment of the present invention.

### DETAILED DESCRIPTION

The following description of advantageous exemplary embodiments of the present invention employs the same or similar reference numerals for the elements that are shown in the various figures and whose function is similar, there being no need to repeat the description of these elements.

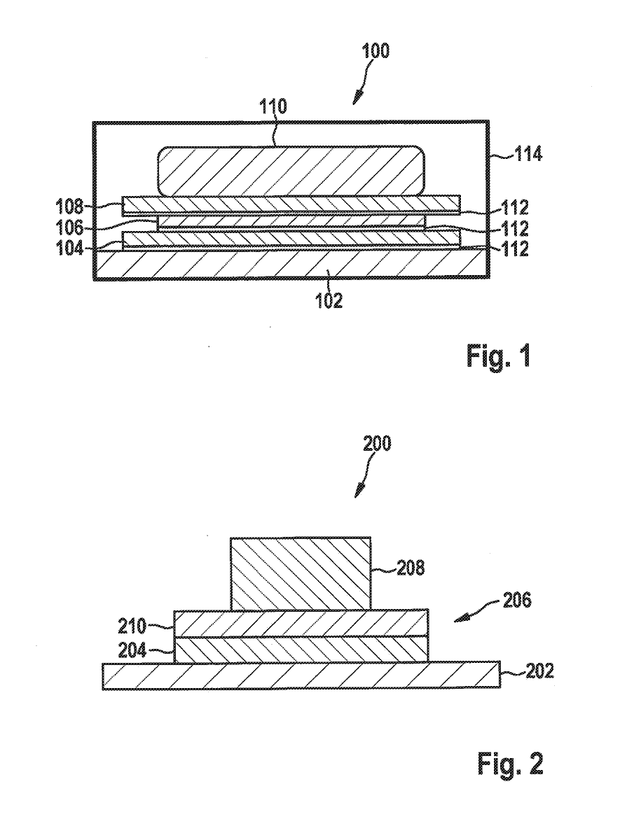

FIG. 1 shows a schematic representation of an electronic system 100 having a radio chip in accordance with the related art. Electronic system 100 is provided as a stacked configuration of a substrate, respectively carrier 102, a radio chip 104 having a thickness of 100 μm, a spacer element, respectively spacer chip 106 of silicon having a thickness of 75 μm, a microcontroller 108 having a thickness of 100 μm and a sensor, respectively sensor packet 110. A chip adhesive 112 having a nominal thickness of 20 μm fixes radio chip 104 to substrate 102, spacer chip 106 to radio chip 104, and microcontroller 108 to spacer chip 106. Electronic system 100 also has a housing 114 in the form of a molded cover in accordance with the related art.

Upon assembly of radio chip system 100, it should be noted that a high frequency circuit of radio chip 104 is defined toward the top side of the chip. Radio chip 104 is normally configured to be installed with a molded cover 114 of a few hundred micrometers. This mold 114 takes the high frequency design into consideration in the configuration of the components of radio chip 104 that are relevant to high frequency.

With reference to a schematic representation, FIG. 2 shows an electronic system 200 in accordance with an exemplary embodiment of the present invention. Electronic system 200 is composed of a carrier 202, a radio chip 204, a spacer element, respectively spacer 206, and an electronic component 208.

As illustrated in FIG. 2, electronic system 200 has a stacked structure. Carrier 202 forms a base of the stack. Carrier 202 is a plate-shaped substrate, such as a printed circuit board, for example. Besides the carrier function, substrate 202 is also configured to supply electric voltage to at least one component of electronic system 200 via printed conductors and/or through holes. Radio chip 204 is mounted on carrier 202. Radio chip 204 is configured for transmitting and/or receiving electromagnetic radiation in one or a plurality of predefined radio bands. Radio chip 204 likewise has a plate-shaped, respectively layered design. Spacer element 206, which is likewise formed as a layer, is mounted on radio chip 204 and thereby spaces radio chip 204 at a distance from electronic component 208 that is mounted on spacer element 206. This is important to the radio transmission function of radio chip 204. Electronic component 208 may be a sensor, for example.

Spacer element, respectively spacer 206 features a material 210 having a predefined permittivity number, respectively dielectric constant. Spacer 206 may be completely or partially formed from material 210. The predefined permittivity number of spacer element 206 makes it possible to maintain, without limitation, the radio transmission functionality of subjacent radio chip 204, independently of further components of electronic system 200 stacked over spacer element 206. The predefined permittivity number of spacer element material 210 may be derived from a predefined thickness of material 210 forming spacer element 206. Alternatively or additionally, the predefined permittivity number may result from a chemical and/or physical composition of material 210.

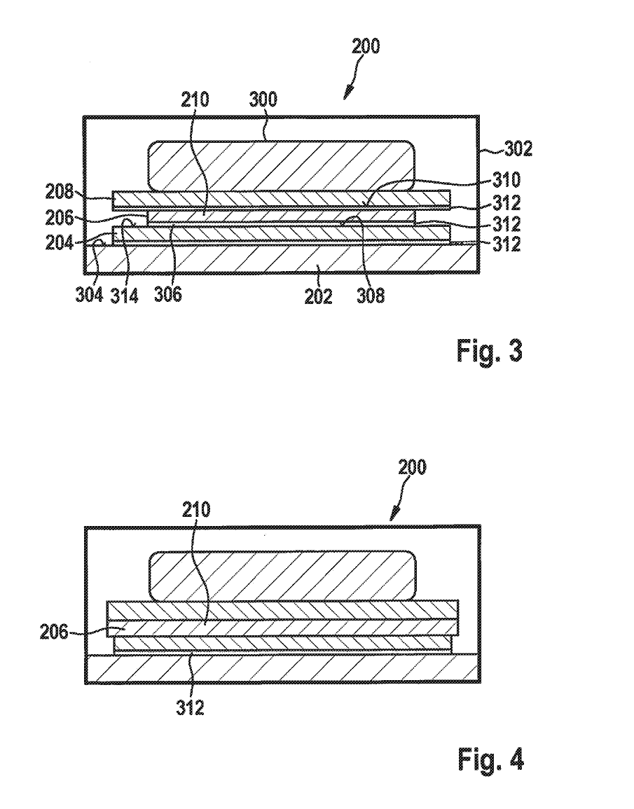

FIG. 3 schematically represents another exemplary embodiment of electronic system 200 introduced here. Here as well, electronic system 200 is in a stacked configuration and, in this case, is expanded by another electronic component 300, as well as by a housing 302. Radio chip 204 is a Bluetooth or IEEE 802.15.4 radio chip, for example. Radio chip 204 has a thickness of 100 μm here.

As illustrated in FIG. 3, carrier 202, radio chip 204, and spacer element 206, as well as electronic component 208 are layered, respectively plate-shaped here; further electronic component 300 is rectangular here and is mounted on electronic component 208 as a termination of the stack. All components 202, 204, 206, 208, 300 are stacked one upon the other by the main sides thereof. The main sides are understood to be those sides that oppose one another and have the largest dimensions in comparison to the remaining sides of components 202, 204, 206, 208, 300. As shown in the illustration, due to the larger dimensions of the main sides thereof, carrier 202, radio chip 204, and electronic component 208 project out laterally from the stack of electronic system 200. Carrier 202 has the largest lateral extent relative to the stack. In addition to further electronic component 300, electronic system 200 may include even more electronic components in accordance with exemplary embodiments. These, in turn, may be stacked upon further electronic component 300.

In the exemplary embodiment of electronic system 200 shown in FIG. 3, material 210 contains silicon dioxide (Si0₃). Here, material 210 is entirely made of silicon dioxide. In accordance with one alternative exemplary embodiment, it is also possible that silicon dioxide make up only one portion of material 210. Silicon dioxide features a relative permittivity of εᵣ˜3.5 and is consequently within the range of the permittivity number of a typical housing for radio chips. It is thus ensured that radio chip 204 is not subject to any frequency shift by using silicon dioxide for spacer element 206 and in view of the structure of electronic system 200. In the exemplary embodiment shown in FIG. 3, material 210 is present in the form of silicon dioxide in a layer thickness of 75 μm. The layer thickness is merely exemplary and may also have a different value.

In the case of the exemplary embodiment of electronic system 200 shown in FIG. 3, further electronic component 300 is a sensor, for example, an MEMS sensor. A physical quantity of a field surrounding electronic system 200 may be recorded, for example, via sensor 300. Electronic component 208 disposed underneath sensor 300 is configured here as a processing unit for controlling and/or analyzing information from further electronic component 300. Processing unit 208 may be a microcontroller, respectively MCU (microcontroller unit) or digital signal processor. Microcontroller 208 may be configured for controlling sensor 300 or for analyzing data from sensor 300, and is present here in a thickness of 100 μm. The thickness of MCU 208 is merely exemplary and may also have a different value.

In the exemplary embodiment of electronic system 200 shown in FIG. 3, housing 302 is formed as a molding compound that is applied to a surface of electronic system 200 and is cured, so that, here, housing 302 forms a mold that closely surrounds the covered region of electronic system 200. As illustrated, the molding compound of housing 302, at least in the lateral dimensions of carrier 202, is applied as the laterally largest element of the stack, so that, in the cured state, housing 302 extends over sensor 300 forming the termination of the stack and, to the side of the stack, to a main side 304 of carrier 202 facing the stack. Thus, housing 302 is configured for completely surrounding all of the regions of components 202, 204, 206, 208, 300 of the stack that are accessible to the molding compound, and for fixing them in position.

In the exemplary embodiment shown in FIG. 3 of electronic system 200 introduced here, besides material 210, spacer element 206 features another material 306. Further material 306 is disposed here in the form of a layer on a first main side 308 of first material 210 facing carrier 202 and corresponds in the lateral dimensions thereof to material 210. Alternatively or additionally, further material 306 maybe disposed on a second main side 310 of first material 210 facing away from carrier 202 and opposing first main side 308. Further material 306 is characterized by a further predefined permittivity number that may differ from the permittivity number of material 210 or be identical thereto. In the case of the exemplary embodiment of electronic system 200 shown in FIG. 3, further material 306 is an adhesive agent 312 for adhering spacer element 206 to a main side 314 of radio chip 204 adjacent to spacer element 206. The adhesive agent, respectively film adhesive 312 is disposed here in an exemplary film thickness of nominally 20 μm on first main side 308 of first material 210. In the case of exemplary electronic system 200 shown in FIG. 3, a sum of the predefined permittivity number of first material 210 and of further predefined permittivity number of further material 306 is within the range of a permittivity number of housing 302.

In the case of the illustrated exemplary embodiment of electronic system 200 on microcontroller 208 for fixing microcontroller 208 in place on spacer 206 and on radio chip 204 for fixing radio chip 204 in place on substrate 202, other adhesive agent layers 312 are disposed thereon.

Upon assembly of an electronic system, the radio chip is configured to define the high-frequency circuit toward the top side of the chip. Chips are normally configured to be installed with a molded cover of a few hundred micrometers. The high frequency design takes this mold into consideration in the configuration of the components that are relevant to high frequency.

Electronic system 200 presented here is configured to allow radio chip 204 and MEMS chips 208, 300 to be installed one over the other within housing 302, thus further chips 208, 300 to be stacked on radio chip 204. Thus, further chips of silicon having a permittivity number of approximately 11 are typically located within the stack. Using the spacer element, respectively spacer 206 having a low dielectric constant, eliminates the risk of subjecting radio chip 204 to a frequency shift, since it precludes any influence of spacer chip 206 on the high frequency component of radio chip 204. Thus, the approach introduced here eliminates the need for any adaptation to the high frequency design of radio chip 204 that is based on a molding compound having a permittivity number of approximately 3 to 4 and a height of at least 100 μm, for example.

In another schematic representation, FIG. 4 shows another exemplary embodiment of electronic system 200 introduced here. The illustrated exemplary embodiment of electronic system 200 corresponds to that shown in FIG. 3, with the distinction here that, instead of silicon dioxide, adhesive agent 312 is used as material 210 for spacer element 206. Since, besides adhesive agent, respectively adhesive 312, no further materials are used for spacer element 206, adhesive layer 312 is dimensioned to be thicker than in the exemplary embodiment shown in FIG. 3, for example, to have a height of nominally 75 μm. A film over wire technique, for example, is suited for applying chip adhesive 312. In this exemplary embodiment, the possibly greater production costs may be compensated by the lower material costs.

Besides the mentioned materials, other materials that may be produced and set as thin substrates, such as other types of glass or already cured molding compound, for example, may conceivably be used in spacer element, respectively spacer 206 illustrated in FIG. 2 through 4.

The thicknesses and functional descriptions indicated in the figures are exemplary; the principle introduced here applies independently of a thickness of the materials used.

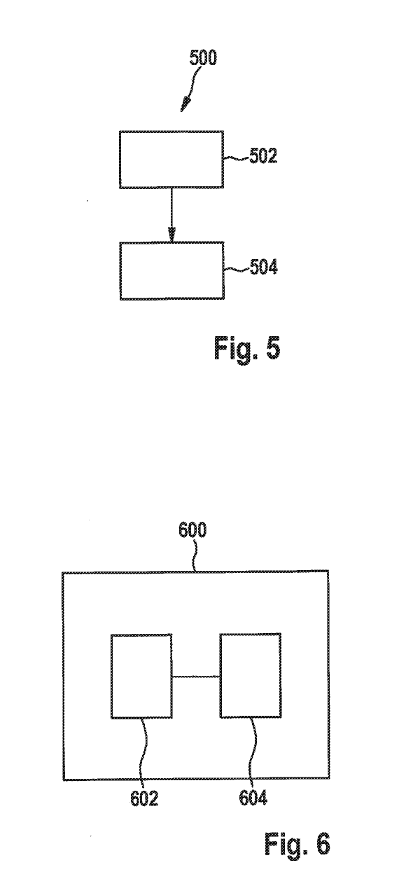

FIG. 5 shows a flow chart of an exemplary embodiment of a method 500 for manufacturing an electronic system. For example, using manufacturing method 500, one of a plurality of electronic systems, such as those introduced in FIG. 2, may be manufactured in an automated process. In a step 502, a carrier, a radio chip, an electronic component, and a spacer element are provided for suitably spacing apart the radio chip and the electronic component. The spacer element has a material having a predefined permittivity number. In a step 504, the carrier, the radio chip, the spacer element, and the electronic component are stacked one over the other in this sequence to produce the electronic system.

FIG. 6 shows a block diagram of an exemplary embodiment of a device 600 for manufacturing an electronic system, for example, the electronic system from FIG. 2. Device 600 may be part of an automated production line. It includes a feeder device 602 and a positioning device 604. Feeder device 602 is configured for providing a radio chip, an electronic component, a spacer element for spacing the electronic component at a distance from the radio chip, and a carrier for supporting the radio chip, the spacer element and the electronic component. Positioning device 604 is configured for positioning the radio chip on the carrier, the spacer element on the radio chip, and the electronic component on the spacer element in order to manufacture the electronic system.

The concept presented here makes it possible to realize products that employ sensors, and a microcontroller having an installed radio front end.

The described exemplary embodiments shown in the figures are only selected exemplarily. Various exemplary embodiments may be combined with one another entirely or by individual features. An exemplary embodiment may also be supplemented by features of another exemplary embodiment.

The method steps presented here may also be repeated and be executed in a sequence other than that described.

If an exemplary embodiment includes an “AND/OR” logic operation between a first feature and a second feature, then this is to be read as the exemplary embodiment in accordance with a first specific embodiment having both the first feature, as well as the second feature and, in accordance with another specific embodiment, either only the first feature or only the second feature.

1-14. (canceled)

15. An electronic system, comprising:
a carrier;
at least one radio chip mounted on the carrier;
a spacer element mounted on the radio chip, the spacer element having a material having a predefined permittivity number; and
at least one electronic component mounted on or above the radio chip.

16. The electronic system of claim 15, wherein the material has a permittivity number that is within a tolerance range of the permittivity number of a molding compound surrounding the electronic component.

17. The electronic system of claim 15, wherein the spacer element has at least one further material having another predefined permittivity number, the further material being disposed on a first main side of the material facing the carrier and/or on a second main side of the material opposite the first main side and facing away from the carrier.

18. The electronic system of claim 17, wherein a predefined thickness of the spacer element is between 50 and 200 μm, the thickness denoting a distance between a first main side and a second main side of the spacer element.

19. The electronic system of claim 17, wherein the material and/or the further material are/is formed as an adhesive agent for adhering to a main side of the radio chip adjacent to the spacer element.

20. The electronic system of claim 15, further comprising:
a housing to at least enclose the electronic component.

21. The electronic system of claim 20, wherein, within a predefined tolerance range of a permittivity number, the predefined permittivity number or a sum of the predefined permittivity number and the other predefined permittivity number corresponds to the portion of the housing adjacent to the radio chip.

22. The electronic system of claim 15, wherein the electronic component and/or the radio chip is configured as a processing unit for controlling at least an actuator and/or analyzing information and/or as a sensor for recording at least one physical quantity.

23. The electronic system of claim 15, further comprising:
an electronic component mounted on the electronic component.

24. The electronic system of claim 23, wherein the electronic component is configured as a processing unit for controlling and/or analyzing information of the further electronic component, and wherein the further electronic component is configured as a sensor for recording at least one physical quantity, the electronic component.

25. A method for manufacturing an electronic system, the method comprising:
providing a carrier, at least one radio chip, at least one electronic component, and a spacer element that is formed with a material having a predefined permittivity number; and
mounting the at least one radio chip on the carrier, the spacer element on the at least one radio chip, and the at least one electronic component on the spacer element to manufacture the electronic system.

26. A device for manufacturing an electronic system, comprising:
a feeder device for providing a carrier, at least one radio chip, at least one electronic component, and a spacer element that is formed with a material having a predefined permittivity number; and
a positioning device for mounting the at least one radio chip on the carrier, the spacer element on the radio chip, and the at least one electronic component on the spacer element to manufacture the electronic system.

27. The device of claim 26, wherein the material has a permittivity number that is within a tolerance range of the permittivity number of a molding compound surrounding the at least one electronic component.

28. A machine-readable storage medium having a computer program, which is executable by a processor, comprising:
a program code arrangement having program code for manufacturing an electronic system, by performing the following:
providing a carrier, at least one radio chip, at least one electronic component, and a spacer element that is formed with a material having a predefined permittivity number; and
mounting the at least one radio chip on the carrier, the spacer element on the at least one radio chip, and the at least one electronic component on the spacer element to manufacture the electronic system.

29. The electronic system of claim 15, wherein the material has a permittivity number that is within a tolerance range of the permittivity number of a molding compound surrounding the electronic component, in particular, the permittivity number of the material being less than 10.

30. The electronic system of claim 15, wherein the material has a permittivity number that is within a tolerance range of the permittivity number of a molding compound surrounding the electronic component, in particular, the permittivity number of the material being between 3 and 5.

31. The electronic system of claim 23, wherein the electronic component is configured as a processing unit for controlling and/or analyzing information of the further electronic component, and wherein the further electronic component is configured as a sensor for recording at least one physical quantity, the electronic component, in particular, being configured as part of the radio chip.
